(19) United States
(12) Patent Application Publication
(10) Pub. No.: US 2026/0305364 A1
(43) Pub. Date: Oct. 1, 2026

(54) U-SHAPED COIL ARRANGEMENT IN A POWER STAGE MODULE

(71) Applicant: TEXAS INSTRUMENTS INCORPORATED, Dallas, TX (US)

(72) Inventor: Sudhir Nagaraj, Dallas, TX (US)

(21) Appl. No.: 19/093,676

(22) Filed: Mar. 28, 2025

(51) Int. Cl. H01L 23/64; H01L 23/29; H01L 23/31; H01L 23/367; H01L 23/498; H01L 25/18

(52) U.S. Cl. CPC H10W 44/501; H10W 40/228; H10W 74/114; H10W 74/40; H10W 90/00; H10W 90/701

(57) ABSTRACT

A circuit comprises a substrate and a die over the substrate. The circuit further includes first and second contacts on the substrate between an edge of the die and an edge of the substrate, the second contact being laterally spaced from the first contact. A first conductive structure extends from the first contact and a second conductive structure extends from the second contact. A conductive trace has first and second ends coupled to the first and second conductive structures respectively, and the conductive trace at least partially overlies the die.

### BACKGROUND

A switching regulator may produce a regulated output voltage by controlling a current through an inductor via one or more switches. Based on the states of the one or more switches, the inductor may store energy from an input or provide energy to an output to produce the regulated output voltage.

### SUMMARY

A circuit includes a substrate, a die over the substrate, a first contact on the substrate, and a second contact on the substrate. The first contact on the substrate is between an edge of the die and an edge of the substrate. The second contact on the substrate is between the edge of the die and the edge of the substrate, and is laterally spaced from the first contact. A first conductive structure extends from the first contact, and a second conductive structure extends from the second contact. The circuit further comprises a conductive trace having first and second ends coupled to the first and second conductive structures respectively, and the conductive trace at least partially overlies the die.

A circuit includes a substrate, a first die over the substrate, a second die over the substrate, and a first pair of contacts on the substrate. The second die is laterally spaced from the first die on the substrate. The first pair of contacts is arranged between an edge of the substrate and an edge of the first die. The second pair of contacts on the substrate is arranged between the edge of the substrate and an edge of the second die. A first conductive trace is coupled to the first pair of contacts and extends away from the edge of the substrate. A second conductive trace is coupled to the second pair of contacts and extends away from the edge of the substrate.

A system includes a first substrate, a first plurality of dies over the first substrate, a second substrate, a second plurality of dies over the second substrate, and a processor. A first plurality of conductive traces each have first and second terminals contacting the first substrate between an edge of the first substrate and an edge of a die of the first plurality of dies. A first additional conductive traces extends over the first plurality of dies. A second plurality of conductive traces each have first and second terminals contacting the second substrate between an edge of the second substrate and an edge of a die of the second plurality of dies. A second additional conductive trace extends over the second plurality of dies. The processor is coupled to the first terminals of the first plurality of conductive traces and the first terminals of the second plurality of conductive traces.

### BRIEF DESCRIPTION OF THE DRAWINGS

FIGS. 1A-1D are schematic diagrams illustrating an example of one or more conductive traces over a substrate.

FIGS. 2A-2D are schematic diagrams illustrating an example variation of FIGS. 1A-1D, further including an additional conductive trace with one or more U-shaped portions.

FIG. 3 is a schematic diagram illustrating an example variation of FIGS. 2A-2D, where the additional conductive trace is arranged above the one or more conductive traces.

FIG. 4 is a schematic diagram illustrating an example variation of FIGS. 2A-2D, where the additional coil is arranged below the one or more conductive traces.

FIG. 5 is a schematic diagram illustrating an example variation of FIGS. 2A-2D, where the additional coil is arranged around the one or more conductive traces.

FIGS. 6A-6C are schematic diagrams illustrating an example variation of FIGS. 1A-1D, further including a support structure under the one or more conductive traces.

FIGS. 7A-7B are schematic diagrams illustrating an example variation of FIGS. 1A-1D.

FIGS. 8A-8D are schematic diagrams illustrating an example of a single U-shaped conductive trace over a substrate.

FIGS. 9-10 are schematic diagrams illustrating examples of power circuits with one or more conductive traces coupled to a load.

FIG. 11 is a schematic diagram illustrating an example variation of FIG. 10, where the load comprises a processor.

FIG. 12 is a schematic diagram illustrating an example circuit layout including the elements of FIGS. 2A-2D.

FIG. 13 is a schematic diagram illustrating an example variation of FIGS. 2A-2D.

FIG. 14 is a schematic diagram illustrating an example of a power circuit with one or more conductive traces coupled to a load.

### DETAILED DESCRIPTION

The drawings are not drawn to scale.

A voltage regulator, such as a direct current (DC) to DC converter, may utilize one or more inductors to store and release energy in the form of a magnetic field. For example, during operation, the voltage regulator may control one or more switches to alternate between storing energy from an input of the regulator, and releasing the stored energy to generate a regulated voltage at an output of the regulator. The voltage regulator may be designed with various topologies (e.g., buck converter, boost converter, buck-boost converter) depending on factors such as input/output voltage, power, efficiency, etc.

In high power applications, designs such as multi-phase and trans-inductor voltage regulator (TLVR) topologies may be utilized to improve the performance of the voltage regulator. For example, multi-phase topologies can be used to distribute the power delivery requirement (e.g., current) across multiple power stages, which can reduce I²R resistive losses. In the case of TLVR, a primary inductor can be coupled between a power stage and a load, and a secondary inductor can be added in a transformer configuration with the primary inductor, which improves transient response due to the secondary inductor acting as a reserve of stored energy.

Power density is an important metric which refers to the area efficiency of power delivery circuitry on a chip. Although utilizing multi-phase and/or TLVR topologies may improve performance, such topologies may also utilize a greater number of inductors, which can negatively the power density. Accordingly, the present disclosure relates to a U-shaped inductor coil arrangement for improving power density.

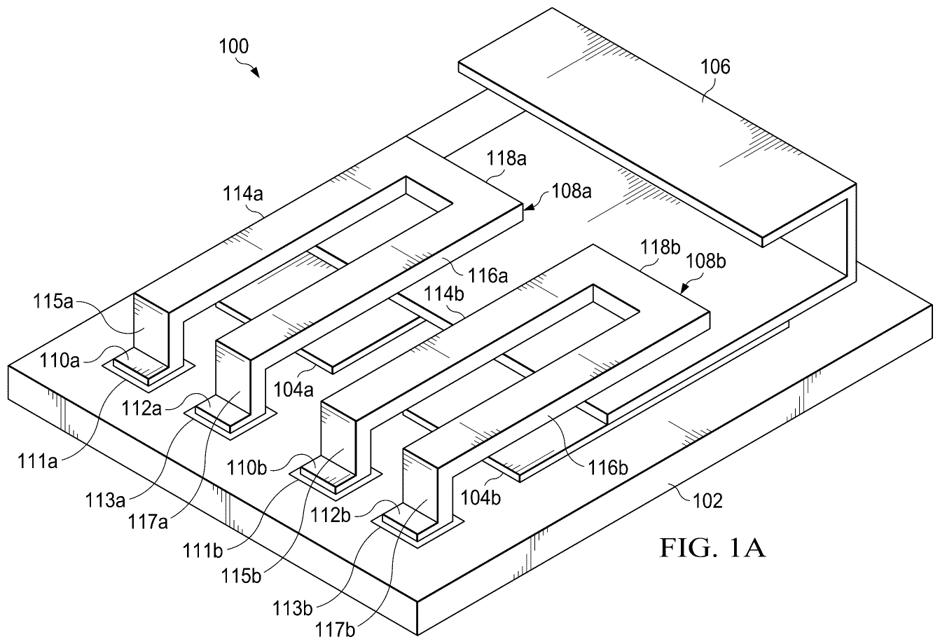

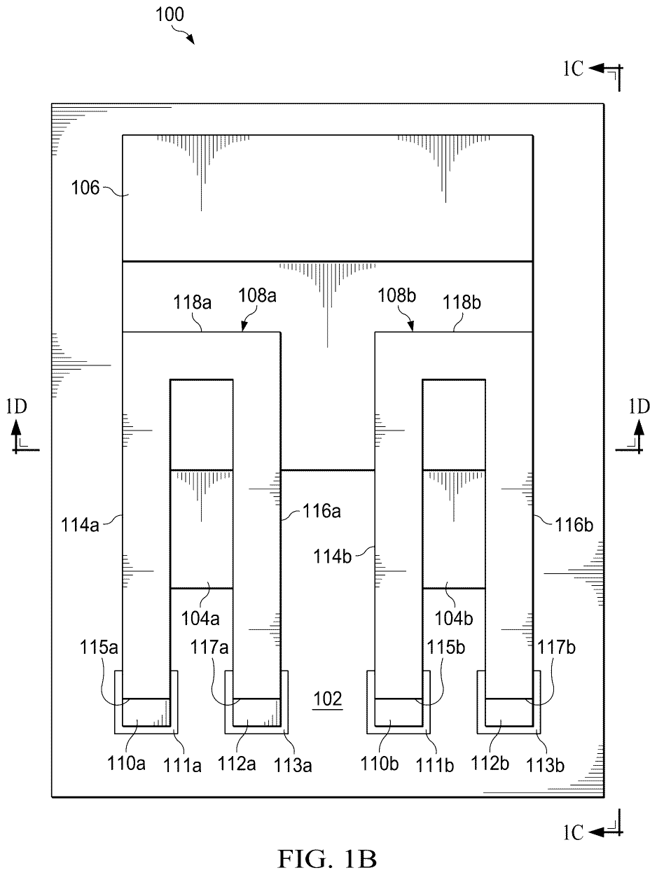

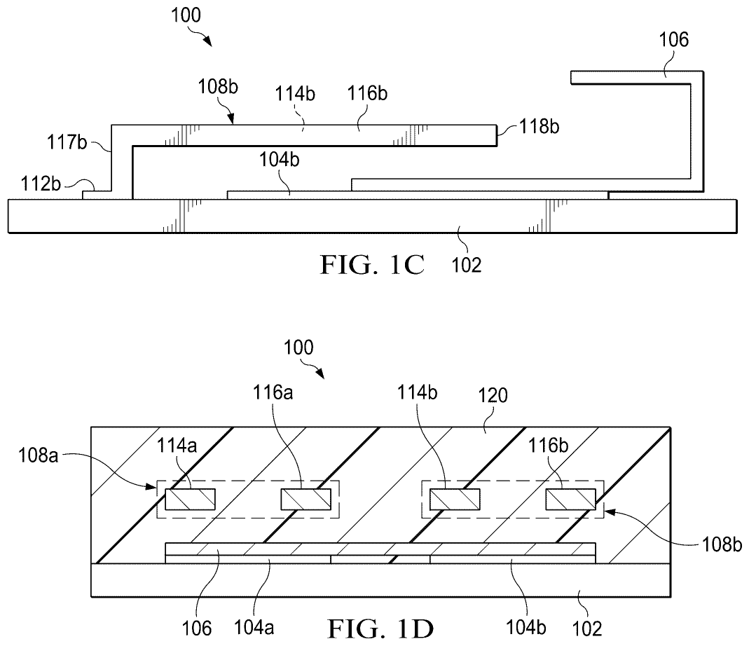

FIGS. 1A-1D illustrate an example electrical structure 100 including one or more conductive traces over a substrate 102. As shown in an isometric view of the electrical structure 100 in FIG. 1A, the electrical structure 100 includes a first die 104a and a second die 104b over the substrate 102. The electrical structure 100 further includes a first contact 111a, a second contact 113a, a third contact 111b, and a fourth contact 113b on the substrate 102. The electrical structure 100 further includes a first conductive trace 108a, a second conductive trace 108b, and a heat sink 106. The contacts 111a and 113a may be considered to form, and thus may be collectively referred to as a first pair of contacts. Further, the contacts 111b and 113b may be considered to form and may be collectively referred to as a second pair of contacts.

In some examples, the first die 104a and the second die 104b comprise a first power stage circuit and a second power stage circuit, respectively. The first and second power stage circuits, for example, correspond to different phases in a multi-phase converter.

In some examples, the contacts 111a, 113a, 111b, 113b comprise conductive contacts which are coupled to the dies 104a, 104b (e.g., within the substrate). For example, a routing layer within the substrate electrically couples to the contacts 111a, 113a to the die 104a, and electrically couples the contacts 111b, 113b to the die 104b. In one example, the substrate 102 comprises a routable lead frame (RLF). For example, the RLF may comprise routing layers of copper (e.g., 3 layers of copper) used for signal routing, power routing, etc. In some examples, the contacts 111a, 113a, 111b, 113b comprise metal (e.g., copper).

The first conductive trace 108a is coupled to the contacts 111a, 113a and the second conductive trace 108b is coupled to the contacts 111b, 113b. As shown, the first conductive trace 108a includes a first base portion 110a coupled to the first contact 111a, and a second base portion 112a coupled to the second contact 113a. The second conductive trace 108b includes a first base portion 110b coupled to the third contact 111b, and a second base portion 112b coupled to the fourth contact 113b. Furthermore, the first conductive trace 108a includes linear portions 114a, 116a, and the second conductive trace 108b includes linear portions 114b, 116b. As shown, the base portions 110a, 112a, 110b, 112b are coupled to the linear portions 114a, 116a, 114b, 116b, respectively, which extend from the base portions (e.g., extend upward from the substrate 102). Throughout the present description, the base portions may be alternatively referred to as conductive bases, conductive structures, conductive legs, or using other similar terminology.

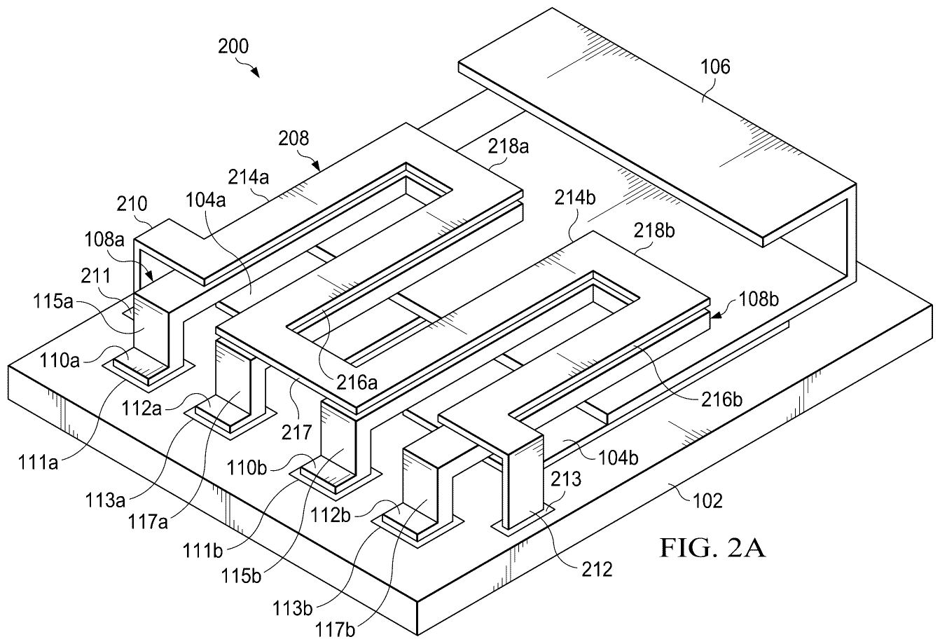

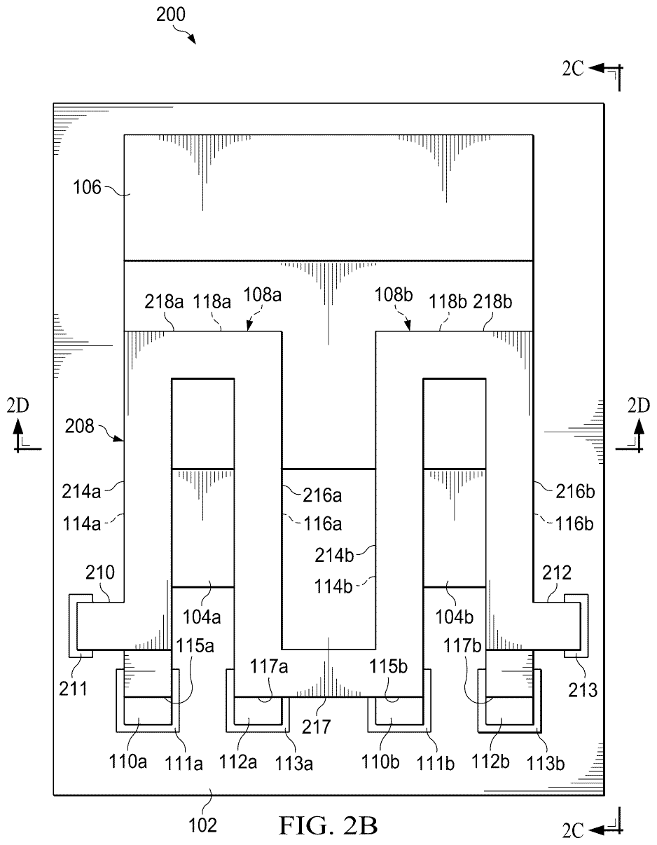

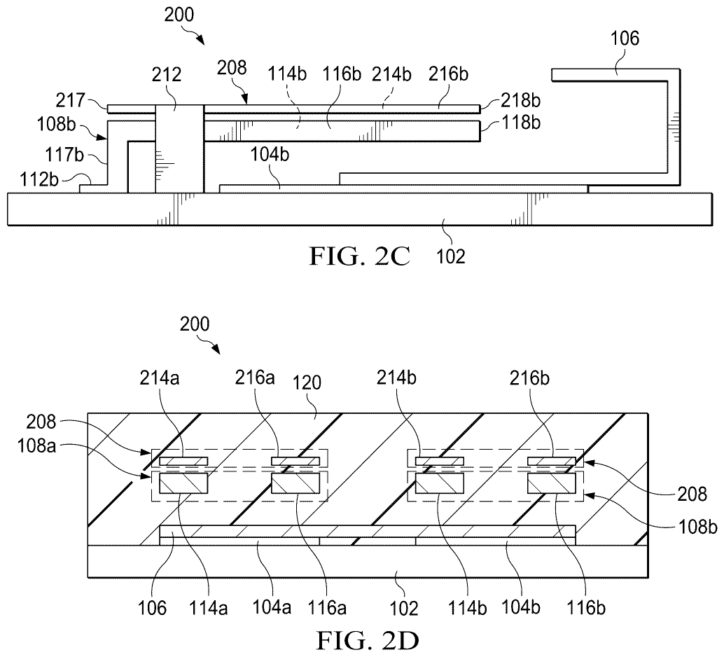

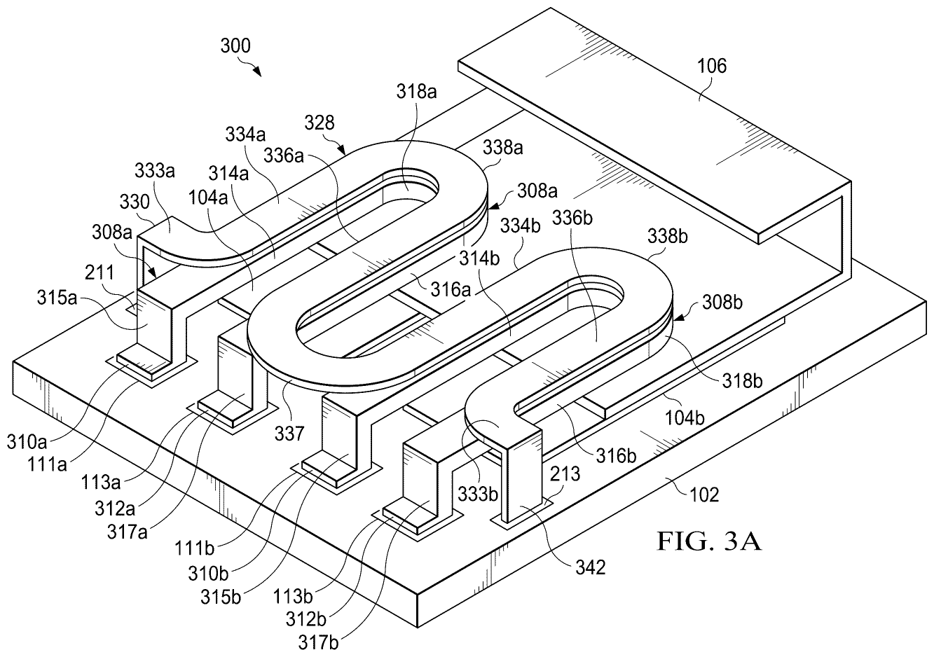

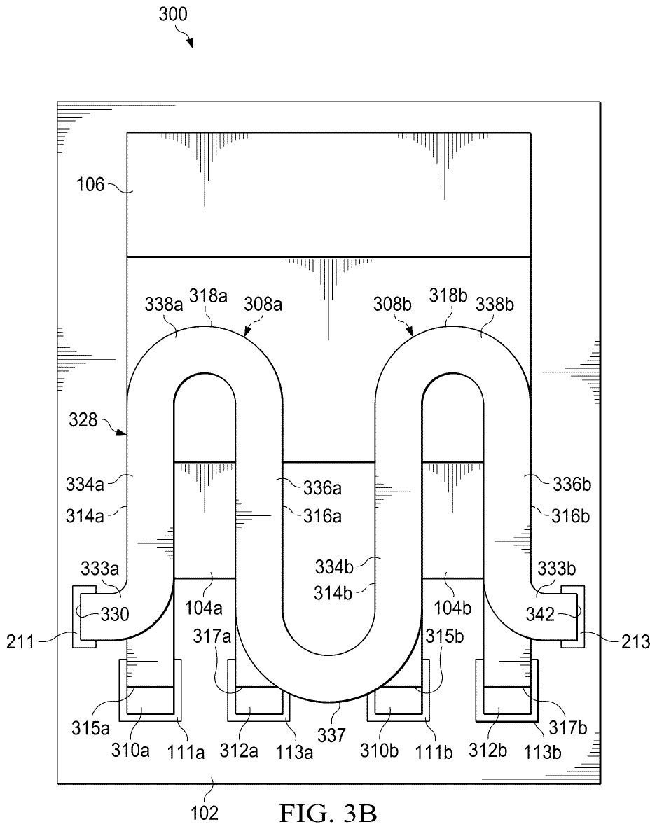

In some examples, the conductive traces 108a, 108b each comprise a U-shape. As shown, the first conductive trace 108a further includes a first linear portion 114a, a second linear portion 116a, and a connecting portion 118a (also referred to as linear/connecting structures or segments). The first linear portion 114a extends from a first end of the conductive trace 108a, and the second linear portion 116a extends from a second end of the conductive trace 108a. As shown, the first linear portion 114a has a first end coupled to the base portion 110a (e.g., via the linear portion 115a), and a second end. The second linear portion 116a has a first end coupled to the base portion 112a (e.g., via the linear portion 116a), and a second end. The connecting portion 118a (e.g., a third linear portion) is coupled between the first linear portion 114a and the second linear portion 116a. As shown, the connecting portion 118a is coupled to the second ends (e.g., ends opposite the first and second ends of the conductive trace 108a) of the linear portions 114a, 116a. The linear portions, in combination with the connecting portion, creates a U-shape in the conductive trace (e.g., 108a/b), such that the terminating ends of the conductive trace are placed over the contacts (e.g., 111a/b, 113a/b). As discussed with reference to the following figures, the connecting portion 118a may comprise a linear conductive segment (e.g., FIGS. 1-2) or a curved conductive segment (e.g., FIGS. 3-5).

As shown, the linear portions 114a, 116a, 114b, 116b approximately extend in parallel with one another (e.g., within a few degrees) in a first direction. Further, the connecting portions 118a, 118b approximately extend in parallel with one another in a second direction, where the second direction is approximately perpendicular to the first direction. The linear portions 115a, 115b, 117a, 117b approximately extend in parallel with one another in a third direction, where the third direction is approximately perpendicular to a plane formed by an upper surface of the substrate 102. In the illustrated example, the conductive traces 108a, 108b at least partially overlie the respective dies 104a, 104b.

In some examples, each conductive trace (e.g., 108a or 108b) has an inductance of approximately 15 nanohenry (nH). In some examples, each conductive trace has a direct current resistance (DCR) of approximately 200-300 microohms (μΩ). Although example values of inductance and resistance are provided, the dimensions of the conductive traces 108a, 108b may be adjusted to achieve alternative values of inductance and/or resistance. Throughout the present description, the conductive traces may be alternatively referred to as conductive bodies, or using other similar terminology.

The heat sink 106 contacts the dies 104a, 104b, and is at least partially over/covering the dies 104a, 104b. The heat sink 106 has a base portion at least partially contacting the plurality of dies, an upper portion above the plurality of contacts, and a connecting portion (e.g., extending away from the substrate 102) coupled to the upper portion and the base portion. The heat sink 106 may include copper or aluminum, for example. The heat sink may conduct and transfer heat that is generated by the dies 104a, 104b during operation. The conductive traces 108a, 108b at least partially overlie the heat sink 106.

The layout of the electrical structure 100 has significant benefits when considering power density. As shown, the contacts 111a, 113a are arranged between an edge of the die 104a and an edge of the substrate 102, and the contacts 111b, 113b are arranged between an edge of the die 104b and the edge of the substrate. Thus, the contacts 111a, 113b, 111b, 113b are arranged in a row on a same side of the substrate 102, which frees space on an opposite side of the substrate (e.g., side closest to heat sink 106) to accommodate larger dies 104a, 104b, or reduce the overall footprint of the electrical structure 100. The placement of the contacts 111a, 113b, 111b, 113b also facilitates placement of the heat sink 106 due to the freed space on the opposite side of the substrate 102. The layout of the electrical structure 100 also benefits routing in a common footprint (e.g., contact placement of the dies 104a, 104b) of power stage modules.

FIGS. 1B and 1C illustrate top and side views of the electrical structure 100, respectively. Illustrated in FIG. 1B is a plane 1C corresponding to the side view illustrated in FIG. 1C. As visible in FIGS. 1B-1C, the conductive traces 108a, 108b extend over the substrate 102, the dies 104a, 104b, and the heat sink 106, which utilizes verticality to further improve the power density. In some examples, as shown, the conductive traces 108a, 108b are separated from the substrate 102 and the dies 104a, 104b by a gap.

FIG. 1D illustrates a cross sectional view from another side (e.g., a front) of the electrical structure 100. Illustrated in FIG. 1B is a plane 1D corresponding to the cross sectional view illustrated in FIG. 1D. As shown in FIG. 1D, the electrical structure 100 further includes a magnetic fill material 120 around the conductive traces 108a, 108b. In some examples, the magnetic fill material 120 comprises a magnetic mold compound, such as a composite material comprising metal particles (e.g., iron, cobalt, and/or nickel) and resin. The magnetic fill material 120 may surround the conductive traces 108a, 108b and increase the inductance of the conductive traces 108a, 108b. Although not illustrated for clarity purposes, the magnetic fill material 120 may also be present in FIGS. 1A-1C.

FIGS. 2A-2D illustrate an example electrical structure 200. In some examples, the electrical structure 200 resembles the electrical structure 100, but differs in that it further includes an additional conductive trace 208. FIGS. 2A, 2B illustrate an isometric view and a top view of the electrical structure 200, respectively. FIG. 2C illustrates a side view of the electrical structure 200. FIG. 2D illustrates a cross sectional view from another side (e.g., a front) of the electrical structure 200.

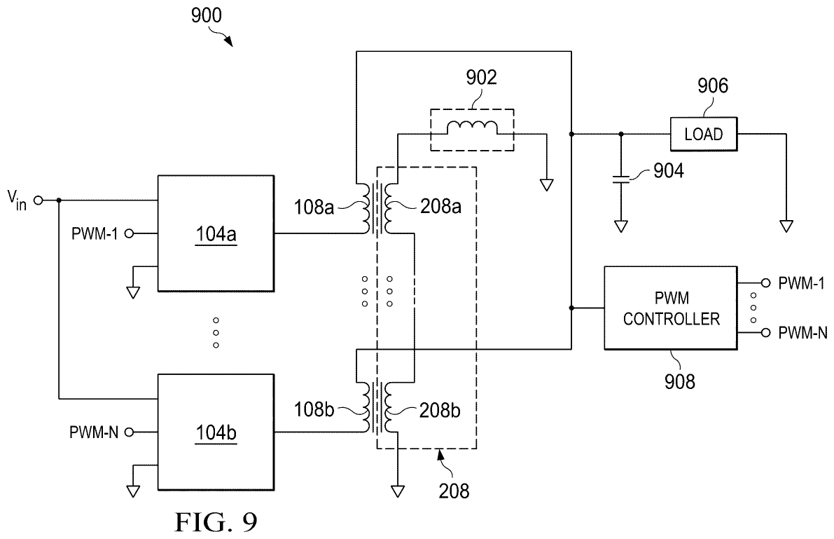

In some examples, the additional conductive trace 208 comprises one or more U-shaped portions. In the illustrated example, the one or more U-shaped portions of the additional conductive trace 208 overlie the conductive traces 108a and 108b. A structure of the additional conductive trace 208 may approximately follow or “trace” the path of the conductive traces 108a, 108b, such that the additional conductive trace 208 is magnetically coupled to the conductive traces 108a, 108b. As shown, the additional conductive trace 208 comprises linear portions 214a, 216a, 214b, 216b over the linear portions 114a, 116a, 114b, 116b respectively, and connecting portions 218a, 218b over the connecting portions 118a, 118b respectively. Furthermore, the additional conductive trace 208 comprises a connecting portion 217 coupled to the linear portions 216a, 214b. In the example of FIGS. 2A-2D, the connecting portions 218a, 218b, 217 each comprise a linear structure. A current through the conductive traces 108a or 108b produces a proportional current through the conductive trace 208 via the magnetic coupling. For example, the conductive traces 108a, 108b, 208 collectively form one or more transformers. The one or more transformers may be part of a TLVR circuit, as discussed with further detail with reference to FIGS. 9-11.

In some examples, the linear portions 214a, 216a, 214b, 216b of the additional conductive trace 208 directly overlie or underlie the respective linear portions 114a, 116a, 114b, 116b of the conductive traces 108a, 108b. Further, the linear portions 114a, 116a, 114b, 116b extend in parallel with one another, and the linear portions 214a, 216a, 214b, 216b extend in parallel with one another and in parallel with the linear portions 114a, 116a, 114b, 116b. The connecting portions 218a, 218b, 217 are perpendicular to the linear portions 214a, 216a, 214b, 216b.

As used herein, the term “overlie” may be used to describe an element that is vertically above another element, while the term “underlie” may be used to describe an element that is vertically below another element. The terms “overlie” and “underlie” may be considered with respect to a reference point, such as the substrate 102. For example, one or more elements may be on top of the substrate 102, and an element closer to the substrate 102 on the vertical plane may be considered to “underlie” an element further from the substrate 102 on the vertical plane.

The electrical structure 200 further includes a contact 211 and a contact 213 on the substrate. In the illustrated example, the contact 211 is arranged between an edge of the substrate 102 and the die 104a, and the contact 213 is arranged between an opposing edge of the substrate 102 and the die 104b. The additional conductive trace 208 further comprises a base portion 210 and a base portion 212. The base portion 210 is coupled to the contact 211, and the base portion 212 is coupled to the contact 213. In some examples, the contacts 211, 213 are coupled to additional components of the electrical structure 200 via a routing layer within the substrate 102. The contacts 211, 213 may comprise a conductive material, such as metal (e.g., copper).

As shown, the linear portion 214a has a first end coupled to the base portion 210, and a second end. The connecting portion 218a has a first end coupled to the second end of the linear portion 214a, and a second end. The linear portion 216a has a first end coupled to the second end of the connecting portion 218a, and a second end. The connecting portion 217 has a first end coupled to the second end of the linear portion 216a, and a second end. The linear portion 214b has a first end coupled to the second end of the connecting portion 217, and a second end. The connecting portion 218b has a first end coupled to the second end of the linear portion 214b, and a second end. The linear portion 216b has a first end coupled to the second end of the connecting portion 218b, and a second end coupled to the base portion 212.

In the electrical structure 200, the additional conductive trace 208 (e.g., secondary coil) is tightly coupled to conductive traces 108a, 108b (e.g., primary coils). For example, the additional conductive trace 208 is arranged along the top of the conductive traces 108a, 108b with a minimum spacing to establish an insulation layer between the coils, which improves the space efficiency/power density of the electrical structure 200. In some examples, the additional conductive trace 208 is a continuous trace, such that it has a minimal area penalty on the chip. These features may also be better suited to vertical power delivery than other potential configurations of phases and inductors, which is beneficial in enterprise applications where the introduction of more advanced processors becomes increasingly limited by the power delivery solution. In vertical power delivery, the power components are placed directly below the load, which reduces the distance that high currents need to travel, and thus reduces I²R resistive losses.

As shown in FIG. 2D, the magnetic fill material 120 may surround the conductive traces 108a, 108b, 208. Although the conductive traces 108a, 108b are illustrating as having a greater (vertical) thickness than the conductive trace 208, the thickness of the conductive traces 108a, 108b may alternatively be less than or equal to the thickness of the conductive trace 208.

FIGS. 3A-3B illustrate an example electrical structure 300. FIG. 3A illustrates an isometric view of the electrical structure 300, while FIG. 3B illustrates a top view of the electrical structure 300. In some examples, the electrical structure 300 resembles the electrical structure 200, but differs in that the connecting portions of the conductive traces (e.g., 108a, 108b, 208a, 208b) each comprise a curvilinear structure.

As shown, the electrical structure 300 comprises a conductive trace 308a and a conductive trace 308b (e.g., similar to 108a, 108b, respectively). The conductive trace 308a is coupled to the contacts 111a, 113a, and the conductive trace 308b is coupled to the contacts 111b, 113b. As shown, the conductive trace 308a comprises a base portion 310a, a linear portion 315a, a linear portion 314a, a curvilinear connecting portion 318a, a linear portion 316a, a linear portion 317a, and a base portion 312a. The base portion 310a is coupled to the contact 111a. The linear portion 315a has a first end coupled to the base portion 310a, and a second end. The linear portion 314a has a first end coupled to the second end of the linear portion 315a, and a second end. The curvilinear connecting portion 318a has a first end coupled to the second end of the linear portion 314a, and a second end. The linear portion 316a has a first end coupled to the second end of the curvilinear connecting portion 318a, and a second end. The linear portion 317a has a first end coupled to the second end of the linear portion 316a, and a second end. The base portion is coupled to the second end of the linear portion 317a and coupled to the contact 113a.

Similarly, the conductive trace 308b comprises a base portion 310b, a linear portion 315b, a linear portion 314b, a curvilinear connecting portion 318b, a linear portion 316b, a linear portion 317b, and a base portion 312b. The base portion 310b is coupled to the contact 111b. The linear portion 315b has a first end coupled to the base portion 310b, and a second end. The linear portion 314b has a first end coupled to the base portion 310b, and a second end. The curvilinear connecting portion 318b has a first end coupled to the second end of the linear portion 314b, and a second end. The linear portion 316b has a first end coupled to the second end of the curvilinear connecting portion 318b, and a second end. The linear portion 317b has a first end coupled to the second end of the linear portion 316b, and a second end. The base portion is coupled to the second end of the linear portion 317b and coupled to the contact 113b.

As shown, the linear portions 315a, 317a, 315b, 317b extend perpendicular to the base portions 310a, 312a, 310b, 312b respectively. Further, in the illustrated example the curvilinear connecting portions 318a, 318b each comprise a curve with an angle of approximately 180 degrees (e.g., a semicircle shape) between the respective linear portions coupled thereto.

The electrical structure 300 further comprises an additional conductive trace 328 coupled to the contacts 211, 213. The additional conductive trace 328 comprises a base portion 330, a curvilinear connecting portion 333a, a linear portion 334a, a curvilinear connecting portion 338a, a linear portion 336a, a curvilinear connecting portion 337, a linear portion 334b, a curvilinear connecting portion 338b, a linear portion 336b, a curvilinear connecting portion 333b, and a base portion 342.

The base portion 330 is coupled to the contact 211. The curvilinear connecting portion 333a has a first end coupled to the base portion 330, and a second end. The linear portion 334a has a first end coupled to the second end of the curvilinear connecting portion 333a, and a second end. The curvilinear connecting portion 338a has a first end coupled to the second end of the linear portion 334a, and a second end. The linear portion 336a has a first end coupled to the second end of the curvilinear connecting portion 338a, and a second end. The curvilinear connecting portion 337 has a first end coupled to the second end of the linear portion 336a, and a second end. The linear portion 334b has a first end coupled to the second end of the curvilinear connecting portion 337, and a second end. The curvilinear connecting portion 333b has a first end coupled to the second end of the linear portion 334b, and a second end. The linear portion 336b has a first end coupled to the second end of the curvilinear connecting portion 333b, and a second end. The curvilinear connecting portion 333b has a first end coupled to the second end of the linear portion 336b, and a second end. The base portion 342 is coupled to the second end of the curvilinear connecting portion 333b and the contact 213.

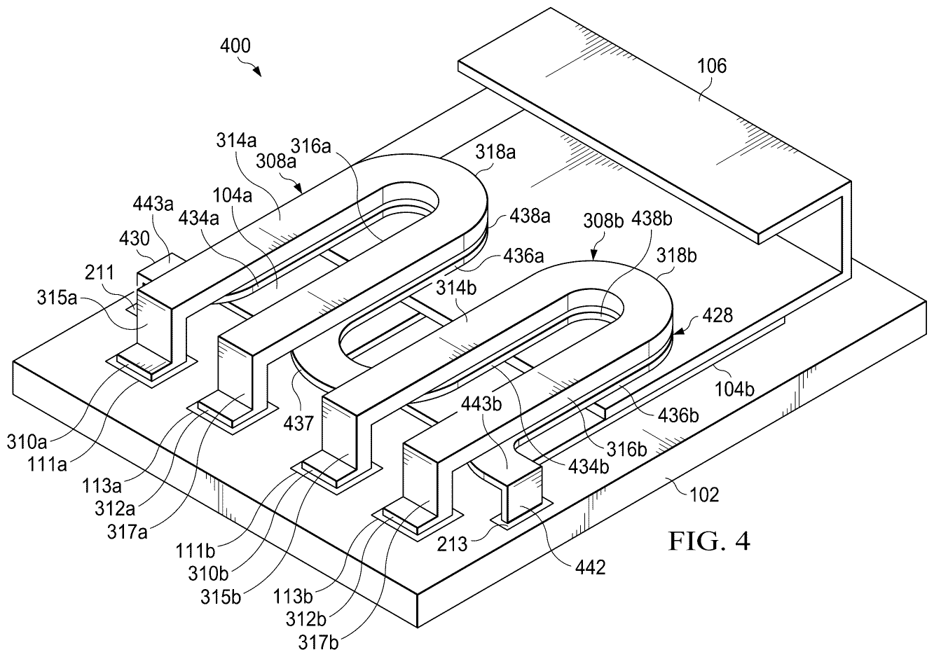

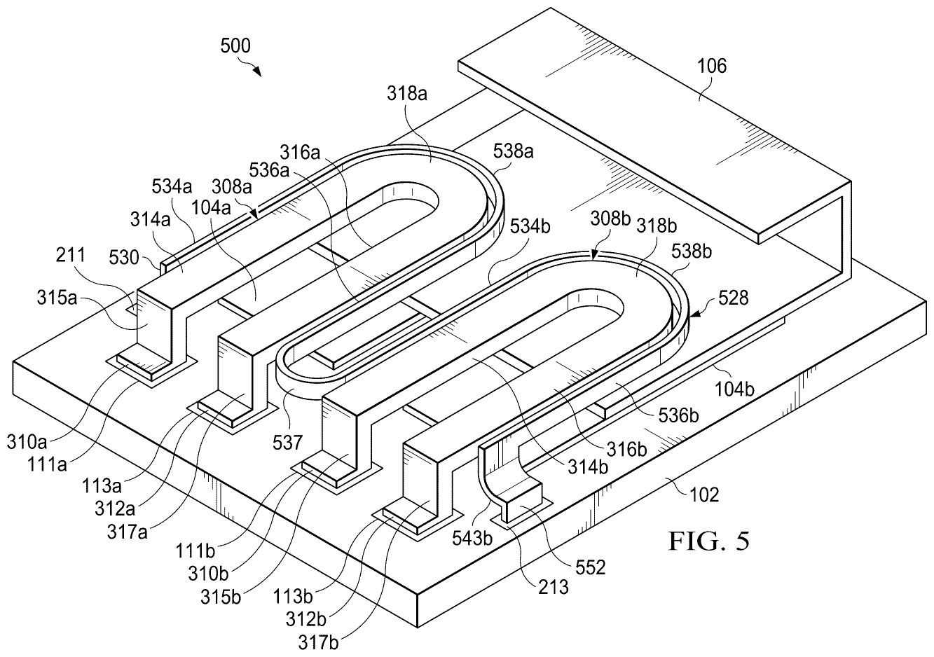

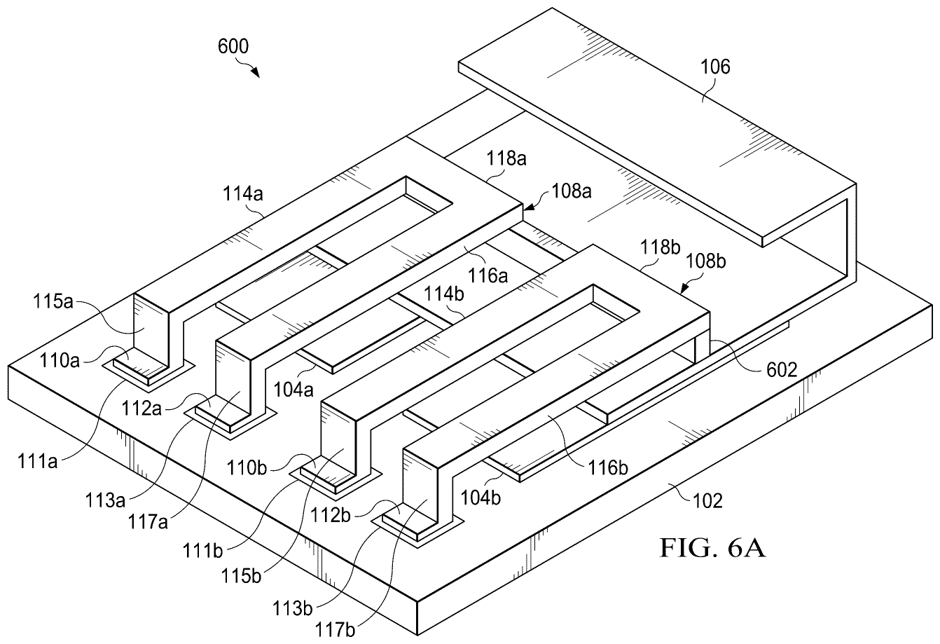

The curvilinear connecting portions 338a, 338b overlie the curvilinear connecting portions 318a, 318b, respectively. In the examples of FIGS. 3-5, the additional conductive trace 328 approximately follows a surface of the conductive traces 308a, 308b to achieve the magnetic coupling. For example, the additional conductive trace 328 may follow an upper surface (FIGS. 3A-3B), a lower surface (FIG. 4), or an outer perimeter surface (FIG. 5) of the conductive traces 308a, 308b. In some examples, the plurality of U-shaped portions of the additional conductive trace 328 are approximately evenly spaced from the upper surface (FIGS. 3A-3B), the lower surface (FIG. 4), or the outer perimeter surface (FIG. 5) of the conductive traces. Accordingly, a spacing between the additional conductive trace 328 and the respective surface remains approximately the same throughout the additional conductive trace 328 structure. The arrangement of the conductive traces 308a, 308b and the additional conductive trace 328 on the substrate 102 minimizes wasted space, which improves the power density of the electrical structure 300.

In some examples, a conductive trace with linear connecting portions (e.g., as in FIGS. 2A-2D) is formed by a stamping process. For example, a tool is used to stamp a flat sheet of material (e.g., copper) into the shape of the coil. In some examples, the stamping process utilizes a stamped coper lead frame technology.

In some examples, a conductive trace with curvilinear connecting portions (e.g., as in FIG. 3) is formed by a bending process. For example, a flat “bar” of material (e.g., copper) is bent using a tool to form the shape of the coil.

FIGS. 4 and 5 illustrate example electrical structures 400 and 500, respectively. The electrical structures 400, 500 resemble the electrical structure 300, but illustrate alternative arrangements of the additional conductive trace (e.g., 328).

As shown in the electrical structure 400, an additional conductive trace 428 (e.g., similar to 328) may be below the conductive traces 308a, 308b. The additional conductive trace 428 comprises a base portion 430, a curvilinear connecting portion 443a, a linear portion 434a, a curvilinear connecting portion 438a, a linear portion 436a, a curvilinear connecting portion 437, a linear portion 434b, a curvilinear connecting portion 438b, a linear portion 436b, a curvilinear connecting portion 443b, and a base portion 442, which may be coupled in a similar manner as the base portion 330, the curvilinear connecting portion 333a, the linear portion 334a, the curvilinear connecting portion 338a, the linear portion 336a, the curvilinear connecting portion 337, the linear portion 334b, the curvilinear connecting portion 338b, the linear portion 336b, the curvilinear connecting portion 333b, and the base portion 342, respectively.

As shown in the electrical structure 500, the additional conductive trace 528 (e.g., similar to 328) may wrap around the conductive traces 108a, 108b. The additional conductive trace 528 comprises a base portion 530, a curvilinear connecting portion 443a, a linear portion 534a, a curvilinear connecting portion 538a, a linear portion 536a, a curvilinear connecting portion 537, a linear portion 534b, a curvilinear connecting portion 538b, a linear portion 536b, a curvilinear connecting portion 543b, and a base portion 552, which may be coupled in a similar manner as the base portion 330, the curvilinear connecting portion 333a, the linear portion 334a, the curvilinear connecting portion 338a, the linear portion 336a, the curvilinear connecting portion 337, the linear portion 334b, the curvilinear connecting portion 338b, the linear portion 336b, the curvilinear connecting portion 333b, and the base portion 342, respectively.

Although FIGS. 4-5 illustrate examples with curvilinear connecting portions (e.g., 438a/b, 433a/b, 538a/b, 533a/b), in alternative examples the connecting portions comprise linear portions (e.g., similar to FIGS. 2A-2D).

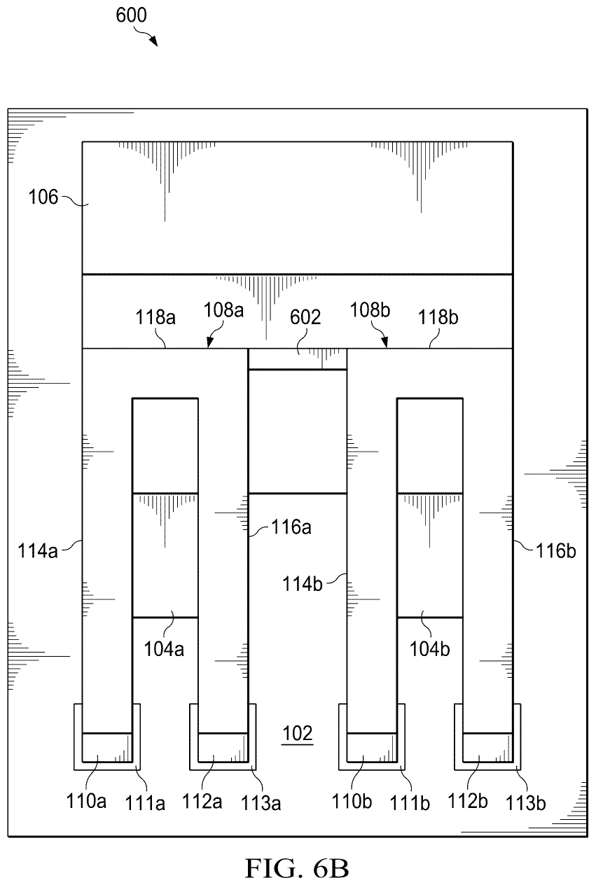

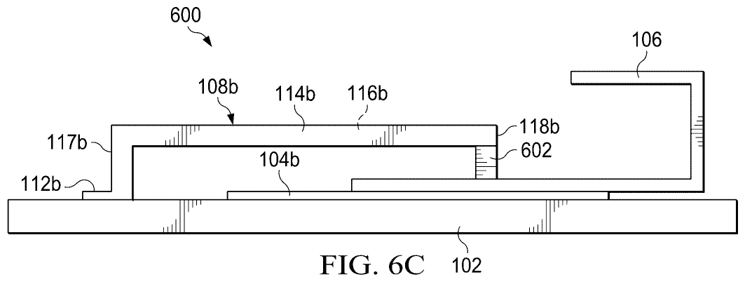

FIGS. 6A-6C illustrate an example electrical structures 600. FIGS. 6A, 6B, 6C illustrate an isometric view, a top view, and a side view of the electrical structures 600, respectively. In some examples, the electrical structures 600 resembles the electrical structure 200, but further includes a support structure 602. The support structure 602 is over the substrate 102, and contacts the connecting portions 118a, 118b. As shown, the support structure is arranged between the connecting portions 118a, 118b and the substrate 102. In some examples, the support structure comprises a non-conductive material, such as a dielectric. Some examples of dielectric materials may be compounds such as silicon dioxide, or materials such as glasses, plastics, ceramics, etc. The support structure 602 may provide structural reinforcement to an otherwise cantilevered structure of the conductive traces 108a, 108b. In some examples, the electrical structures 600 further includes the additional conductive trace (e.g., 208), for example, as described with reference to FIGS. 2A-2D and throughout the present disclosure. Furthermore, although a linear/straight support structure 602 is shown in FIG. 6, in other examples the support structure 602 is curvilinear/curved, and is implemented in the context of FIG. 3, FIG. 4, or FIG. 5, for example.

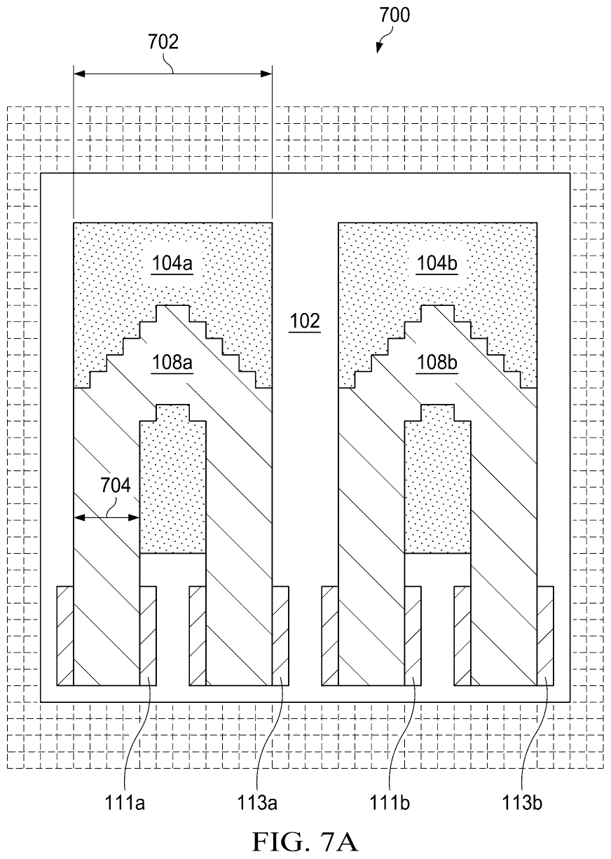

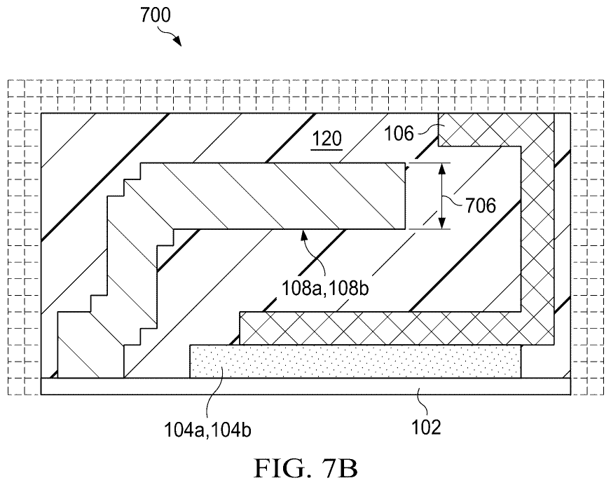

FIGS. 7A-7B illustrate an example electrical structure 700. In some examples, the electrical structure 700 is a variation of the electrical structure 100, with specific scale and/or dimensions indicated by a grid. The illustration in FIG. 7A corresponds to a top view of the electrical structure 700, while the illustration in FIG. 7B corresponds to a side view.

Illustrated in FIG. 7A are contacts 111a, 113a, 111b, 113b arranged in a row on a substrate 102. Further illustrated are dies 104a, 104b on the substrate, and conductive traces 108a, 108b extending over the dies 104a, 104b. The conductive trace 108a is coupled to the contacts 111a, 113a, and the conductive trace 108b is coupled to the contacts 111b, 113b. In the example of FIG. 7, the conductive traces 108a, 108b comprise a curvilinear U-shaped structure. As previously discussed, the conductive traces 108a, 108b may alternatively comprise a linear U-shaped structure.

Further illustrated in FIG. 7B (omitted from FIG. 7A for clarity) is a heat sink 106. The heat sink contacts the dies 104a, 104b and extends upwards (e.g., away) from the substrate. In the illustrated example, the heat sink 106 comprises a first horizontal portion contacting the dies 104a, 104b, and a second horizontal portion over the first horizontal portion. A vertical portion couples the first and second horizontal portions together. In the illustrated example, a length of the second horizontal portion is less than a length of the first horizontal portion. Further illustrated is the magnetic fill material 120. As shown, the magnetic fill material 120 surrounds the conductive traces 108a, 108b. Furthermore, the magnetic fill material 120 fills a void between the conductive traces 108a, 108b and the heat sink 106 and/or dies 104a, 104b.

In some examples, each box in FIGS. 7A-7B corresponds to a dimension of 0.25 millimeters (mm) by 0.25 mm. For example, the die 104a has a width 702 of 3 mm, and a linear portion of the conductive trace 108a (extending from the contact 111a) has a width 704 of 1 mm. As shown in the FIG. 7B, the conductive traces 108a, 108b may have a thickness 706 of 1 mm. Other dimensions can be inferred from the dimensional grid of FIGS. 7A-7B. In some examples, as shown in FIG. 7A, the circuit 700 has a total footprint of approximately 9×10 mm. Although the conductive traces 108a, 108b are illustrated as having a “step” structure, the step structure may be understood to approximate a curved structure (e.g., as in FIGS. 3-5) within the dimensional grid.

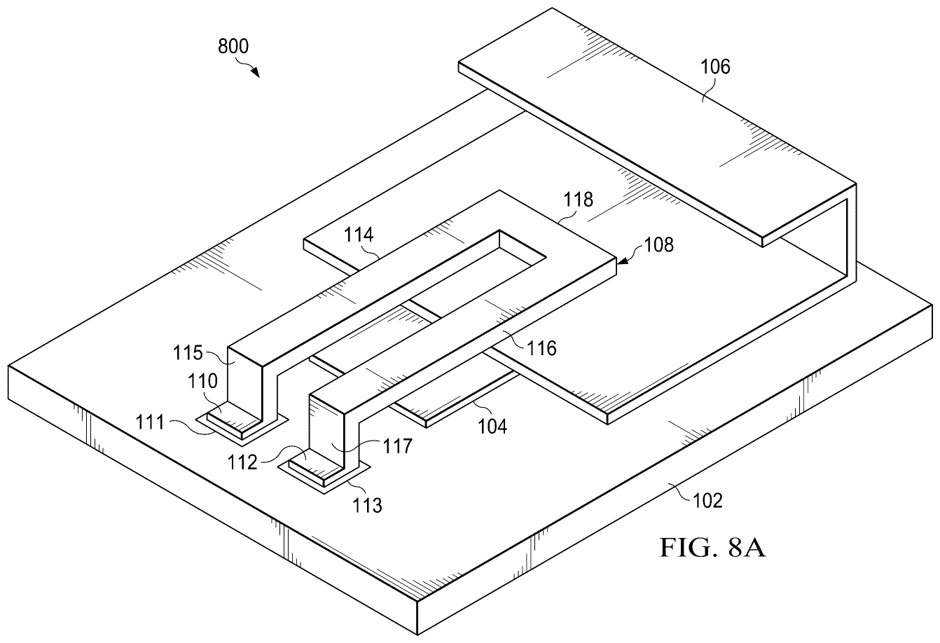

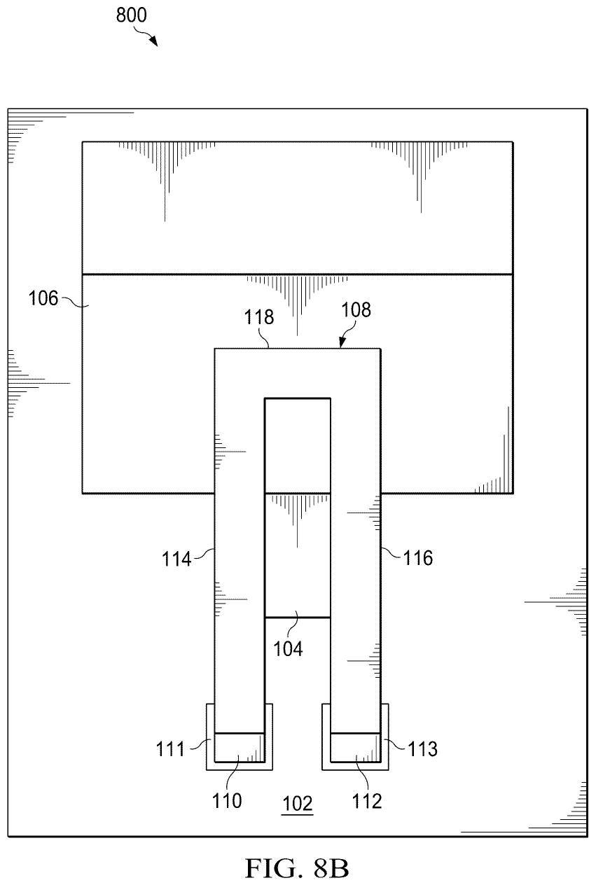

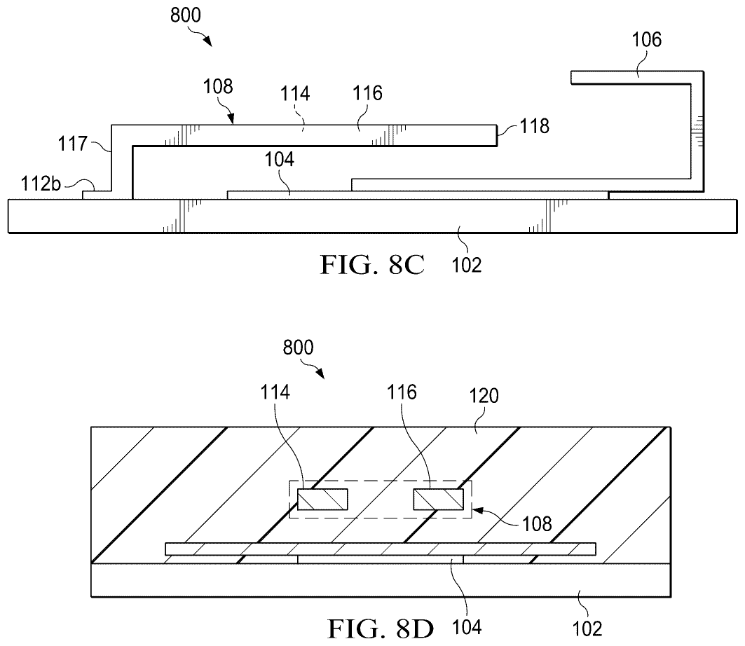

FIGS. 8A-8D illustrate an example electrical structure 800. In some examples, the electrical structure 800 resembles the electrical structure 100, but differs in that it includes a single conductive trace 108. For example, the electrical structure 800 is used operate a single phase of a DC-to-DC converter. Accordingly, the electrical structure 800 may have a smaller total footprint than the electrical structure 100. FIGS. 8A, 8B, 8C, 8D illustrate an isometric view, top view, side view, and cross sectional view (e.g., from a front) of the electrical structure 800, respectively.

As shown, a die 104 is on a substrate 102. In some examples, the die 104 comprises a power stage die, and the substrate 102 comprises an RLF. A first contact 111 and a second contact 113 are arranged on the substrate 102 between an edge of the die 104 and an edge of the substrate 102. A conductive trace 108 comprises a base portion 110, a linear portion 115, a linear portion 114, a connecting portion 118, a linear portion 116, a linear portion 117, and a base portion 112. The base portion 110 is coupled to the contact 111. The linear portion 115 has a first end coupled to the base portion 110, and a second end. The linear portion 114 has a first end coupled to the second end of the linear portion 115, and a second end. The connecting portion 118 has a first end coupled to the second end of the linear portion 114, and a second end. The linear portion 116 has a first end coupled to the second end of the connecting portion 118, and a second end. The linear portion 117 has a first end coupled to the second end of the linear portion 116, and a second end. The base portion 112 is coupled to the second end of the linear portion 117 and is coupled to the contact 113.

Similar to other FIGS., the connecting portion 118 may comprise a linear (e.g., straight) structure or a curvilinear (e.g., curved) structure. For example, the linear structure may be formed using a stamping process, while the curvilinear structure may be formed using a bending process.

FIG. 9 illustrates an example circuit 900. In some examples, the circuit 900 comprises a TLVR circuit.

As shown, the circuit 900 includes circuit components as described with reference to FIGS. 1-2 and throughout the present disclosure. The circuit 900 includes the dies 104a, 104b, and the conductive traces 108a, 108b, 208 (illustrated as 208a and 208b). In the example of FIG. 9, the conductive traces are illustrated (and may alternatively be referred to) as inductors. The circuit 900 further includes a conductive trace (e.g., an inductor) 902, a capacitor 904, a load 906, and a pulse width modulation (PWM) controller 908. In some examples, the load 906 comprises a processor, such as a central processing unit (CPU) or a graphics processing unit (GPU).

The die 104a and the die 104b each have a first input, a second input, a third input, and an output. The first inputs are coupled to an input voltage terminal upon which an input voltage Vᵢₙ is received. The second inputs are coupled to respective outputs of the PWM controller 908. As shown, the die 104a receives a control signal PWM-1 and the die 104b receives a control signal PWM-N from the PWM controller 908. In the illustrated example, the third inputs are coupled to ground.

In some examples, the die 104a and the die 104b each comprise a power stage circuit, which may be used within a voltage regulator. Each power stage circuit may comprise devices such as field effect transistors (FETs), driver circuits, protection circuits, etc. for power delivery operation. A central controller (e.g., PWM controller 908) may be coupled to multiple power stage circuits and control the operation of the power stage circuits via control signals (e.g., PWM-1 through PWM-N).

The conductive trace 108a has a first terminal coupled to the output of the die 104a, and a second terminal coupled to a first terminal of the load 906. Similarly, the second conductive trace 108b has a first terminal coupled to the output of the die 104b, and a second terminal coupled to the first terminal of the load 906. The capacitor 904 has a first terminal coupled to the first terminal of the load 906, and a second terminal coupled to ground. The second terminal of the load 906 is also coupled to ground.

The PWM controller 906 has an input coupled to the first terminal of the load 906, and N number of output terminals. For example, a total of N dies (illustrated by ellipses) are included in the circuit 900, corresponding to a total of N number of phases of the TLVR. The N number of dies receive the PWM signals PWM-1 through PWM-N, which may control switching operation of each die (e.g., each power phase circuit) to generate a regulated output voltage at the load 906 (e.g., based on feedback from the load voltage). Furthermore, the circuit 900 includes N number of conductive traces (e.g., similar to 108a, 108b, 208a, 208b—illustrated by ellipses) coupled to each corresponding die of the N number of dies.

In the illustrated example, the conductive traces 208a and 208b are illustrated as separate conductive traces electrically coupled in series, which is a circuit equivalent of the single conductive trace 208 illustrated in FIGS. 2A-2D. Further illustrated is an conductive trace 902 coupled in series with the conductive traces 208a, 208b. The conductive trace 208b has a first terminal, and a second terminal coupled to ground. The conductive trace 208a has a first terminal, and a second terminal coupled to the first terminal of the conductive trace 208b. The conductive trace 902 has a first terminal coupled to ground, and a second terminal coupled to the first terminal of the conductive trace 208a. In some examples, the conductive trace 902 comprises a compensation inductor electrically coupled in series with the additional conductive trace/inductor 208.

The conductive traces (inductors) 208a, 208b are arranged in transformer configurations with the conductive traces (inductors) 108a, 108b, respectively. For example, the conductive trace 108a forms a primary winding of a first transformer, and the conductive trace 208a (e.g., first portion of the additional conductive trace 208) forms a secondary winding of the first transformer. Furthermore, the conductive trace 108b forms a primary winding of a second transformer, and the conductive trace 208b (e.g., second portion of the additional conductive trace 208) forms a secondary winding of the second transformer. In each transformer, a current through the primary winding induces a proportional current through the secondary winding via magnetic flux. Accordingly, a current through the conductive traces 208a, 208b is proportional to a current through the conductive traces 108a, 108b. The conductive traces 208a, 208b act as a reserve of energy to improve transient response in high power applications. For example, when the load 906 experiences a transient and suddenly draws a large amount of current, the stored energy in the conductive traces 208a, 208b can quickly provide energy to the system to improve the transient response. Compared to other energy storage techniques, such as the use of a large number of capacitors, the conductive traces 208a, 208b achieve higher power density on the chip. The U-shaped coil arrangement, discussed throughout the present disclosure, further improves the power density when utilizing a multiple coil (108a/b and 208a/b) design.

Optionally, the conductive trace 902 (e.g., an inductor) is further included, while in other example the conductive trace 902 is omitted from the circuit 900. When present, the conductive trace 902 is coupled in series with the conductive traces 208a, 208b. In some examples, the conductive trace 902 provides compensation/correction to the current, or acts as a further energy storage. For example, the conductive trace 902 is used to adjust the total inductance (and therefore current) in the secondary loop, which allows for fine tuning of the transient response.

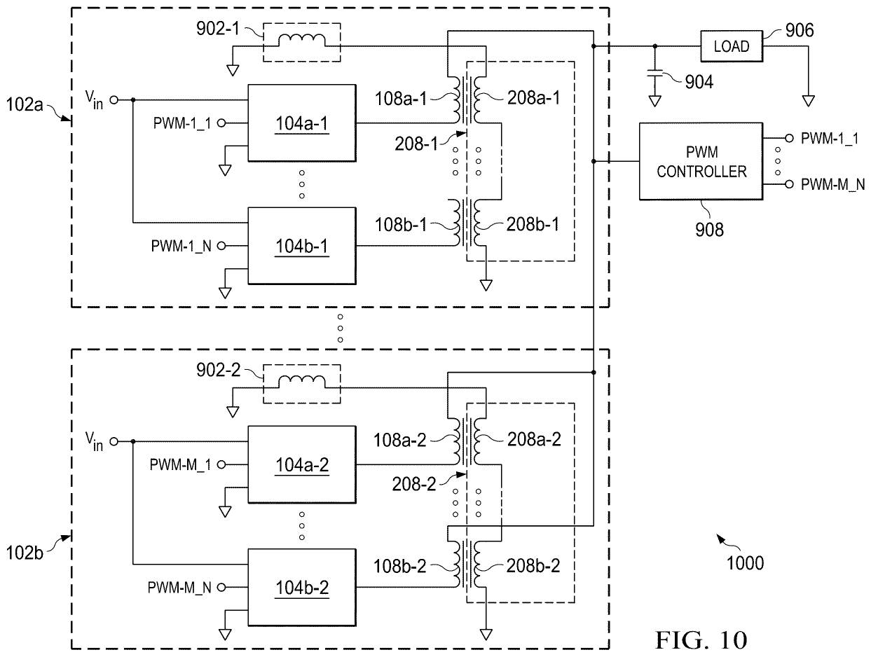

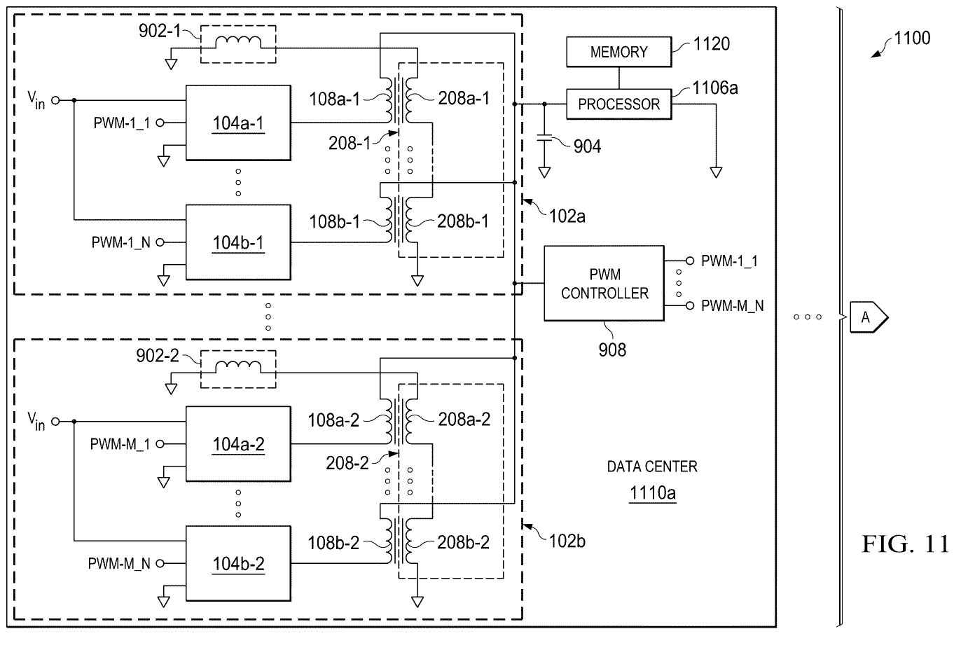

FIG. 10 illustrates an example circuit 1000. In some examples, the circuit 1000 is a variation of the circuit 900, further including an additional power module. For example, a first power module comprises the dies 104a-1, 104b-1 and conductive traces 108a-1, 108b-1, 208a-1, 208b-1, 902-1. Further, up to an Mth power module comprises the dies 104a-2, 104b-2, 108a-2, 108b-2, 208a-2, 208b-2, 902-2. The first through Mth power modules may be on different substrates (e.g., circuit boards) which, for example, can be modularly added or remove from the system to increase or decrease the number of power stages of the TLVR. As shown, the conductive traces 208a-1, 208b-1 may form a single trace (e.g., a U-shaped conductive trace) 208-1, and the conductive traces 208a-2, 208b-2 may form a single trace 208-2.

As shown, the first power module may correspond to a substrate 102a, and the second power module may correspond to a substrate 102b, similar to the substrate 102 described with reference to FIGS. 1-2 and throughout the present disclosure. In some examples, elements illustrated with ellipses (e.g., 104, 108, 208) may include further elements coupled in a similar manner not shown in FIG. 10.

In some examples, the substrate 102a and the substrate 102b each comprise an RLF structure, and a bottom surface of the RLF structure has a plurality of pads (e.g., contacts) that may be coupled (e.g., soldered) onto a motherboard of a larger system (e.g., the circuit 1000). Similar to the circuit 900, further illustrated is the capacitor 904, the load 906, and the PWM controller 908. The PWM controller 908 of FIG. 10 may provide signals PWM-1_1 through PWM-1_N for the first power module (e.g., dies 104a-1 through 104b-1) and provide signals up to PWM-M_1 through PWM-M_N for the Mth power module (e.g., dies 104a-2 through 104b-2). Although in the present example M is equal to 2, in alternative examples M is a value greater than 2.

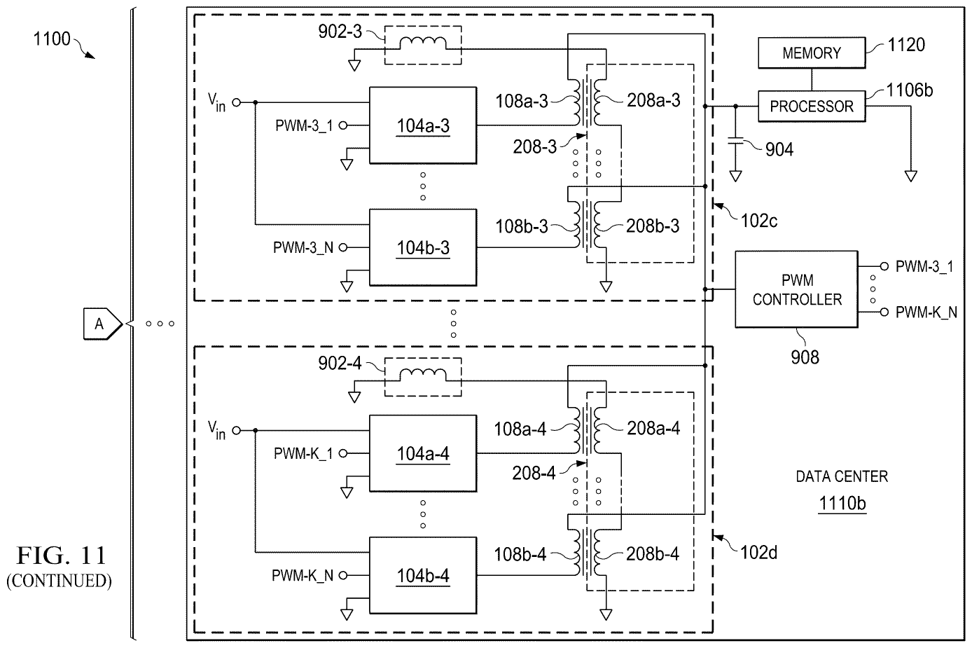

FIG. 11 illustrates an example circuit 1100. In some examples, the circuit 1100 is a variation of the circuit 1000, implemented within a data center 1110a and/or 1110b. As shown, the data centers 1110a, 1110b, respectively, each comprise one or more processors 1106a, 1106b (e.g., in place of the load 906) and a memory 1120a, 1120b. The one or more processors 1106a, 1106b are coupled to the respective memories 1120a, 1120b, and may be configured to execute instructions stored in the memory 1120 to perform various operations. In some examples, the processors comprise CPU(s) and/or GPU(s). In one example, in the case of a CPU, the power draw of the CPU is in the range of 400-500 Amps (A), and M (e.g., number of power modules) is in the range of 16-24. In another example, in the case of a GPU, the power draw of the GPU is up to 1000 A, and M is in the range of 48-60. Although two data centers 1110a, 1110b are shown, in other examples the circuit 1100 comprises further data centers (illustrated by ellipses) with a similar circuit structure as the data center 1110a or 1110b.

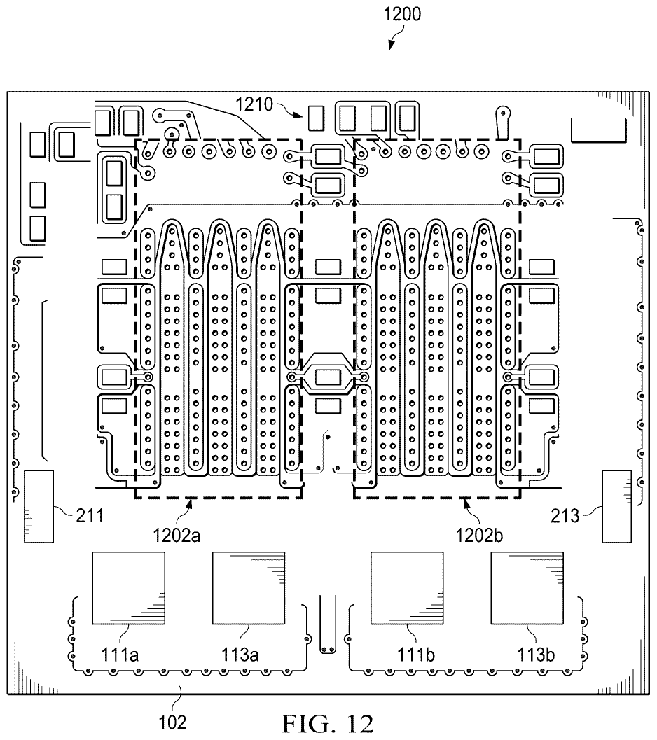

FIG. 12 illustrates an example electrical structure 1200 including the elements of FIGS. 2A-2D. As shown, the electrical structure 1200 includes the contacts 111a, 113a, 111b, 113b, 211, 213 on the substrate 102. Further illustrated are a first set of contacts 1202a, and a second set of contacts 1202b. The first and second sets of contacts 1202a, 1202b may correspond to contacts on the dies 104a, 104b, respectively. For example, the dies 104a, 104b may be soldered to the contacts 1202a, 1202b, respectively, on the board. In some examples, the board comprises an RLF, as previous described. Further illustrated are a set of contacts 1210. In some examples, one or more passive components (e.g., capacitors or inductors) are coupled to the board via the set of contacts 1210.

In some examples, the contacts 111a, 111b each correspond to a switch node. For example, the contacts 111a, 111b are coupled to the output of the dies 104a, 104b, respectively, upon which voltages V_{sw-a} and V_{sw-b} are provided. Further, the contacts 113a, 113b each correspond to an output voltage node. For example, the contacts 113a, 113b are coupled to a load (e.g., 906).

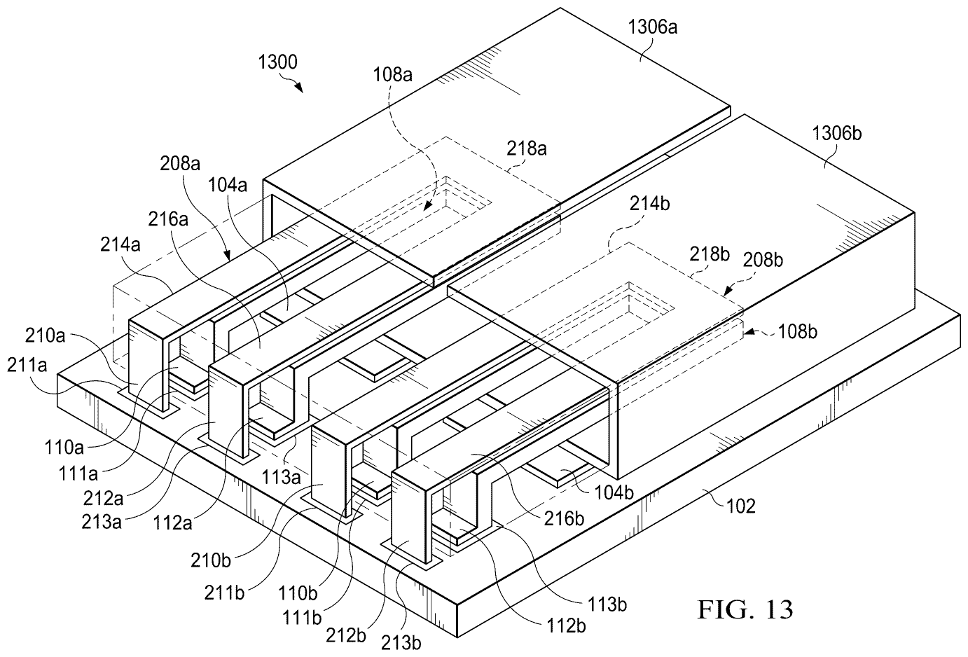

FIG. 13 illustrates an example circuit 1300. In some examples, the circuit 1300 is a variation of the electrical structure 200. As shown, in place of the additional conductive trace 208, the circuit 1300 includes a first additional conductive trace 208a and a second additional conductive trace 208b. In place of the contacts 211, 213, the circuit 1300 includes contacts 211a, 213a, 211b, 213b. In place of the heat sink 106, the circuit 1300 includes a first heat sink 1306a and a second heat sink 1306b.

The conductive trace 208a overlies the conductive trace 108a. As shown, the conductive trace 208a may be approximately aligned with the conductive trace 108a. For example, the linear portions 214a, 216a extend in parallel with and/or are centered over the linear portions 114a, 116a, respectively. Additionally or alternatively, the connecting portion 218a extends in parallel with and/or is centered over the connecting portion 118a. The conductive traces 108a, 208a may be magnetically coupled to one another, as previously described. As shown, the contacts 211a, 213a are arranged between the contacts 111a, 113a and an edge of the substrate 102.

Similarly, the conductive trace 208b overlies the conductive trace 108b, and may be approximately aligned with the conductive trace 108b. Further, the contacts 211b, 213b are arranged between the contacts 111b, 113b and the edge of the substrate 102.

In some examples, a routing layer within the substrate couples the conductive traces 208a, 208b together. For example, within the routing layer, the contact 213a is coupled to the contact 211b (e.g., as shown in the circuit schematics of FIGS. 9-11).

The first heat sink 1306a is arranged over the first die 104a and contacts the first die 104a. The first heat sink 1306a extends toward and outer edge of the substrate 102, around the conductive traces 108a, 208a, and over the conductive traces 108a, 208b. As shown, the first heat sink 1306a comprises a base portion, a connecting portion, and an upper portion. The base portion contacts the die 104a. The vertical portion has a first end coupled to the base portion, and a second end. The upper portion is coupled to the second end of the vertical portion.

The second heat sink 1306b is arranged over the second die 104b and contacts the second die 104b. The second heat sink 1306b extends toward an opposing outer edge of the substrate 102 as the first heat sink 1306a, around the conductive traces 108b, 208b, and over the conductive traces 108b, 108b. As shown, the second heat sink 1306b comprises a base portion, a connecting portion, and an upper portion. The base portion contacts the die 104b. The vertical portion has a first end coupled to the base portion, and a second end. The upper portion is coupled to the second end of the vertical portion.

In some examples, the configuration of the heat sinks 1306a, 1306b is more space efficient when only two dies (e.g., 104a, 104b) are on the substrate 102, while the configuration of the heat sink 106 of FIGS. 1A-1D provides more flexibility when more than two dies are on the substrate 102. Although not illustrated for clarity, the circuit 1300 may further include a magnetic fill material (e.g., 120) around the conductive traces, as described throughout the present disclosure.

Although specific examples have been discussed, it will be appreciated that elements from such examples may be exchanged and/or combined without departing from the scope of the present disclosure. For example, the separate coil (208a, 208b) and/or heatsink (1306a, 1306b) designs of FIG. 13 can be implemented in the context FIGS. 2-5, etc.

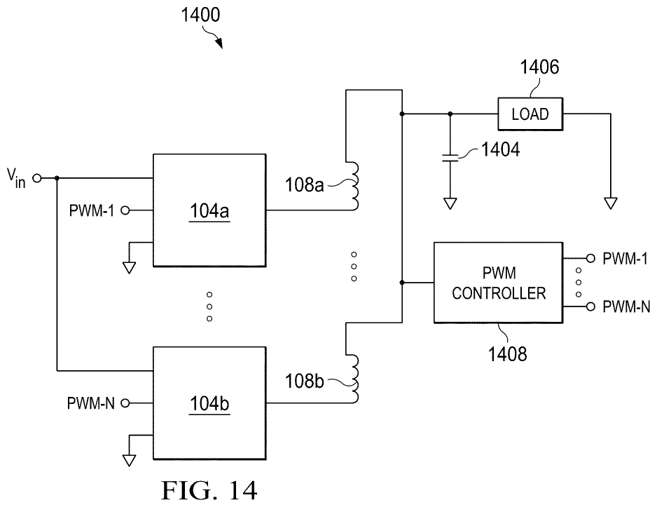

FIG. 14 illustrates an example circuit 1400. In some examples, the circuit 1400 is a variation of the circuit 900, corresponding to a non TLVR circuit. As shown, the circuit 1400 includes the dies 104a, 104b, conductive traces 108a, 108b, capacitor 1404, load 1406, and PWM controller 1408. The dies 104a, 104b each have a first input, a second input, a third input, and an output. The first inputs are coupled to an input voltage terminal upon which Vᵢₙ is received. The second inputs are coupled to respective outputs of the PWM controller 1408, and receive signals PWM-1 through PWM-N. The third inputs are coupled to ground. The output of the die 104a is coupled to a first terminal of the conductive trace 108a, and the output of the die 104b is coupled to a first terminal of the conductive trace 108b. A second terminal of the conductive trace 108a is coupled to a second terminal of the conductive trace 108b and coupled to the load 1406. The capacitor 1404 has a first terminal coupled to the load 1406 (also coupled to the second terminals of the conductive traces 108a, 108b) and a second terminal coupled to ground. The PWM controller 1408 has an input coupled to the load 1406 and to the first terminal of the capacitor 1404.

The methods are illustrated and described above as a series of operations or events, but the illustrated ordering of such operations or events is not limiting. For example, some operations or events may occur in different orders and/or concurrently with other operations or events apart from those illustrated and/or described herein. Also, some illustrated operations or events are optional to implement one or more aspects or examples of this description. Further, one or more of the operations or events depicted herein may be performed in one or more separate operations and/or phases. In some examples, the methods described above may be implemented in a computer readable medium using instructions stored in a memory.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors are described herein, other transistors (or equivalent devices) may be used instead with little or no change to the remaining circuitry. For example, a field effect transistor, a bipolar junction transistor (BJT—e.g. NPN or PNP), insulated gate bipolar transistors (IGBTs), and/or junction field effect transistor (JFET) may be used in place of or in conjunction with the devices described herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a gallium nitride substrate (GaN) or a gallium arsenide substrate (GaAs).

While certain elements of the described examples are included in an integrated circuit and other elements are external to the integrated circuit, in other examples, additional or fewer features may be incorporated into the integrated circuit. Also, some or all of the features illustrated as being external to the integrated circuit may be included in the integrated circuit and/or some features illustrated as being internal to the integrated circuit may be incorporated outside of the integrated circuit. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of that parameter. Modifications are possible in the described examples, and other implementations are possible, within the scope of the claims.

What is claimed is:

1. A circuit comprising:
a substrate;
a die over the substrate;
a first contact on the substrate between an edge of the die and an edge of the substrate;
a second contact on the substrate between the edge of the die and the edge of the substrate, wherein the second contact is laterally spaced from the first contact;
a first conductive structure extending from the first contact;
a second conductive structure extending from the second contact; and
a conductive trace having first and second ends coupled to the first and second conductive structures respectively, wherein the conductive trace at least partially overlies the die.

2. The circuit of claim 1, wherein a bottom surface of the conductive trace is spaced from the substrate and the die.

3. The circuit of claim 1, further comprising a magnetic fill material around the conductive trace.

4. The circuit of claim 1, wherein the conductive trace comprises:
a first linear portion extending from the first end of the conductive trace;
a second linear portion extending from the second end of the conductive trace; and
a third linear portion connecting the first and second linear portions at ends opposite the first and second ends of the conductive trace respectively.

5. The circuit of claim 4, further comprising a support structure over the substrate and contacting the third linear portion of the conductive trace.

6. The circuit of claim 1, wherein the conductive trace comprises:
a first linear conductive segment extending from the first end of the conductive trace;
a second linear conductive segment extending from the second end of the conductive trace; and
a curved conductive segment connecting the first and second linear conductive segments at ends opposite the first and second ends of the conductive trace respectively.

7. The circuit of claim 1, further comprising a heat sink contacting the die and at least partially over the die, wherein the conductive trace at least partially overlies the heat sink.

8. The circuit of claim 1, further comprising:
a third contact on the substrate;
a fourth contact on the substrate;
a third conductive structure extending from the third contact;
a fourth conductive structure extending from the fourth contact; and
an additional conductive trace having first and second ends coupled to the third and fourth conductive structures respectively, wherein the additional conductive trace is over the conductive trace, below the conductive trace, or around an outer edge of the conductive trace.

9. A circuit comprising:
a substrate;
a first die over the substrate;
a second die over the substrate and laterally spaced from the first die on the substrate;
a first pair of contacts on the substrate arranged between an edge of the substrate and an edge of the first die;
a second pair of contacts on the substrate arranged between the edge of the substrate and an edge of the second die;
a first conductive trace coupled to the first pair of contacts and extending away from the edge of the substrate; and
a second conductive trace coupled to the second pair of contacts and extending away from the edge of the substrate.

10. The circuit of claim 9, further comprising:
a first contact on the substrate;
a second contact on the substrate; and
an additional conductive trace having first and second ends coupled to the first and second contacts respectively;
wherein the additional conductive trace comprises a plurality of U-shaped portions.

11. The circuit of claim 10, wherein the plurality of U-shaped portions of the additional conductive trace are approximately evenly spaced from an upper surface, a lower surface, or an outer perimeter surface of the first conductive trace and the second conductive trace.

12. The circuit of claim 10, wherein the first and second conductive traces comprise linear segments extending in parallel with one another, wherein the plurality of U-shaped portions comprise a plurality of linear segments extending in parallel with one another and in parallel with the linear segments of the first and second conductive traces, and wherein each linear segment of the plurality of U-shaped portions is directly over or directly under a corresponding linear segment of the first and second conductive traces.

13. The circuit of claim 10, further comprising a load coupled to the first conductive trace and the second conductive trace.

14. The circuit of claim 13, further comprising a pulse width modulation (PWM) controller having an input coupled to the load, a first output coupled to the first die, and a second output coupled to the second die.

15. The circuit of claim 10, further comprising a compensation inductor electrically coupled in series with the additional conductive trace.

16. The circuit of claim 10, wherein the first conductive trace and a first portion of the additional conductive trace form a first transformer of a trans-inductor voltage regulator (TLVR), and wherein the second conductive trace and a second portion of the additional conductive trace form a second transformer of the TLVR.

17. The circuit of claim 9, further comprising a heat sink having a base portion at least partially contacting the plurality of dies, an upper portion above the plurality of conductive traces, and a connecting portion coupled to the upper portion and the base portion.

18. A system comprising:
a first substrate;
a first plurality of dies over the first substrate;
a first plurality of conductive traces each having first and second terminals contacting the first substrate between an edge of the first substrate and an edge of a die of the first plurality of dies;
a first additional conductive trace extending over the first plurality of dies;
a second substrate;
a second plurality of dies over the second substrate;
a second plurality of conductive traces each having first and second terminals contacting the second substrate between an edge of the second substrate and an edge of a die of the second plurality of dies;
a second additional conductive trace extending over the second plurality of dies; and
a processor coupled to the first terminals of the first plurality of conductive traces and the first terminals of the second plurality of conductive traces.

19. The system of claim 18, further comprising a pulse width modulation (PWM) controller having an input coupled to the processor, and a plurality of outputs coupled to the first and second pluralities of dies.

20. The system of claim 19, wherein the first plurality of conductive traces are magnetically coupled to the first additional conductive trace, and wherein the second plurality of conductive traces are magnetically coupled to the second additional conductive trace.
